(19) United States
(12) Patent Application Publication
(10) Pub. No.: US 2022/0057710 A1
(43) Pub. Date: Feb. 24, 2022

(54) METHOD AND APPARATUS FOR STAMP GENERATION AND CURING

(71) Applicant: Applied Materials, Inc., Santa Clara, CA (US)

(72) Inventors: Michael Y. YOUNG, Cupertino, CA (US); Ludovic GODET, Sunnyvale, CA (US); Robert J. VISSER, Menlo Park, CA (US)

(21) Appl. No.: 17/489,551

(22) Filed: Sep. 29, 2021

Related U.S. Application Data
(62) Division of application No. 16/290,635, filed on Mar. 1, 2019.

(51) Int. Cl. G03F 7/00

(52) U.S. Cl. CPC G03F 7/0002

(57) ABSTRACT

Methods and apparatus for stamp generation are disclosed using nano-resist and ultra violet blocking materials. In one non-limiting embodiment, a method of producing a copy of a stamp for generating electrical/optical components is disclosed comprising: providing the stamp; coating a bottom surface of the stamp with a ultra violet blocking material; curing the ultra violet blocking material on the bottom surface; contacting the stamp to a target substrate covered with a layer of imprint resist; curing the imprint resist with ultraviolet blocking material during the contacting of the stamp to the target substrate; and releasing the stamp from the target substrate with the cured layer of imprint resist.

### CROSS REFERENCE TO RELATED APPLICATIONS

This application is a divisional of U.S. Application Ser. No. 16/290,635, filed Mar. 1, 2019, which is hereby incorporated by reference in its entirety.

### BACKGROUND

### Field

Aspects of the disclosure relate to stamping technology. More specifically, aspects of the disclosure relate to stamping technology using ultra-violet radiation curing technologies for fast and efficient replication of stamp features.

### Description of the Related Art

Conventional processes for using stamping technology have many drawbacks that inhibit such techniques from being more widely used. In some applications, a substrate is covered with a layer of resist and a “stamp” is contacted with the layer of resist. Details from the stamp are transferred to the layer of resist. Subsequent curing processes cure the layer of resist. A drawback to such processing is that layers of resist may be laid upon the substrate at thicknesses greater than necessary (i.e. at the residual thickness layer (RTL)). The layer of resist, after curing, may still be in place thus limiting the overall accuracy of the placement of details from the stamp. Such method challenges affect both binary grating and slanted grating types of designs.

Other problems encountered during these types of processes include rough edges of the finalized product and inaccurate placement of materials within the replicated copy resulting in a non-homogeneous copy of the stamp.

There is a need, therefore, to provide for accurate stamping onto layers of resist such that excess resist is not present after stamping, resulting in a more accurate stamp.

There is a further need to provide a method of stamp reproduction that is economical and fast to speed production requirements.

There is a further need to provide a method that will eliminate rough edges and non-homogenous structures in the replicated pattern.

There is a further need to provide a method that will provide for accurate copies of different types of gratings.

### SUMMARY

In one non-limiting embodiment, a method of producing a copy of a stamp for generating electrical/optical components is disclosed comprising: providing the stamp; coating a bottom surface of the stamp with a ultra violet blocking material; curing the ultra violet blocking material on the bottom surface; contacting the stamp to a target substrate covered with a layer of imprint resist; curing the imprint resist with ultraviolet blocking material during the contacting of the stamp to the target substrate; and releasing the stamp from the target substrate with the cured layer of imprint resist.

In another non-limiting embodiment, a method for producing a stamp is disclosed, comprising: providing a host substrate, coating the host substrate with coating layer, processing the host substrate with the coating layer with a photolithography tool to produce a surface to be replicated, treating the surface to be replicated with an anti-stick material, filling gaps of the stamp with a ultra violet blocking layer, curing the ultra violet blocking layer, placing a layer of material on to the surface to be replicated with the ultra violet blocking layer, placing an adhesion layer to the layer of material on the surface to be replicated to produce an arrangement, producing a controlled air gap between the arrangement and a backing, filling the controlled air gap with polydimethylsiloxane, curing the gap filled with the polydimethylsiloxane, separating the arrangement with the backing at the anti-stick material, producing a top stamp portion, placing the top stamp portion over a target imprint substrate with a layer of resist, contacting the top stamp portion to the target imprint substrate with the layer of resist, removing the top stamp portion from the target imprint substrate with the layer of resist; and curing the layer of resist on the target imprint substrate.

In another non-limiting embodiment, a method of making an electrical/optical component is disclosed comprising: placing a stamp containing a surface for replicating the electrical/optical component over a substrate covered with a layer of resist, stamp having a surface coating of ultra violet blocking material, establishing contact between the substrate covered with the layer of nanoparticle resist and the stamp, imparting radiation to the substrate covered with the layer of nano-particle resist and the stamp, solidifying at least a portion of the nano-particle resist with the radiation not protected by the ultra violet blocking material, separating the nano-particle resist covered substrate from the stamp; and removing sections of residual resist from the stamp.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a depiction of a prior art method for polydimethylsiloxane (PDMS) stamp imprinting for binary fin grating.

FIG. 2 is a depiction of an ultra-violet blocking layer stamp pickup fabrication method for a PDMS stamp.

FIG. 3 is a depiction of a ultra-violet blocking layer stamp pickup fabrication method of a slanted grating PDMS stamp.

FIG. 4 is a method using an angle deposited ultra-violet blocking layer for a deposition fabrication method for a PDMS binary stamp.

FIG. 5 is a method using an angle deposited ultra-violet blocking layer for a deposition fabrication method for a PDMS slanted grating stamp.

FIG. 6 is a method for an underfilled ultra violet blocking layer for a PDMS stamp with binary fin features to make no residual layer imprinting.

FIG. 7 is a method for an underfilled ultra violet blocking layer for a PDMS stamp with slanted fin features to make no residual layer imprinting.

FIG. 8 is a method for producing an underfilled ultra-violet blocking layer for a PDMS stamp to make no residual layer imprinting.

FIG. 9 is a method of using an imprint master with ultra-violet blocking patterns to make a no residual layer imprinting of a binary grating.

FIG. 10 is a method of using an imprint master with ultra-violet blocking patterns to make a no residual layer imprinting of a slanted grating.

FIG. 11 is a method using an imprint master with ultra-violet blocking patterns to make a no residual layer imprint.

FIG. 12 is a prior art depiction of printing a binary fin grating.

FIG. 13 is a prior art depiction of printing a slanted fin grating.

FIG. 14 is a method of printing a binary fin grating using an example methodology of a described embodiment.

FIG. 15 is a method of printing a slanted fin grating using an example methodology of a described embodiment.

FIG. 16 is a method of producing a binary fin grating using roll to roll imprinting.

FIG. 17 is a prior art method of using nano-particle resist for producing a mold protrusion.

FIG. 18 is a method for using nano-particle resist to produce a mold protrusion.

FIG. 19 is a second method for using nano-particle resist to produce a mold protrusion.

FIG. 20 is a process flow diagram for producing a mold protrusion using ligand exchange and alcohol development.

FIG. 21 is a diagram of nano-imprint technology using imprint resist that solidifies upon ultra-violet (UV) radiation exposure.

### DETAILED DESCRIPTION

In embodiments disclosed, methods and apparatus for producing copies of a stamp for production of electrical/optical components are provided. Electrical/optical components include, for example, high refractive index grating fins on high refractive index waveguide combiner (WGC) substrates. Substrates of different types may be used, including, but not limited to, silicon. Different materials coating the substrate, called resist, may be used for receiving a stamping to preserve the details of the stamp during processing. The details of the methods and apparatus disclosed reproduce the fine details of the stamp in quick and economical steps. The methods also limit the amount of lost materials, like excessive usage of resist, resulting in a more environmentally friendly method.

In the embodiments provided, different types of curing methods may be used, such as using ultra-violet radiation on layers of resist that are configured to harden upon exposure to such radiation. In some embodiments, only sections of a total imprint may be exposed to radiation, therefore curing some parts of the imprint of a stamp, while other sections of the imprint may remain uncured until later. In still other embodiments, solutions or materials may be used to allow a stamp to be accurately released from a layer of resist laid upon a substrate, thereby preventing excessive force from being used during separation of the stamp from the resist/substrate combination.

In other embodiments provided, traveling methods are used where resist is conveyed to a substrate during substrate movement and wherein a roller is used to imprint the resist as the substrate moves beneath the roller. Combination of curing techniques may then be used on the resist/substrate combination, such as exposure to ultra-violet radiation. Such radiation may cure the resist during processing to provide quick replication of stamp features. Pressure and heat may also be used on the resist to increase production rates.

In other embodiments, different types of resist may be used to help speed production rates. In some embodiments, resist configured to be more homogeneous during replication activities is used to prevent the presence of rough edges of replicated structures. The resist may also be configured to cure upon exposure of ultra-violet radiation, heat or other external forces.

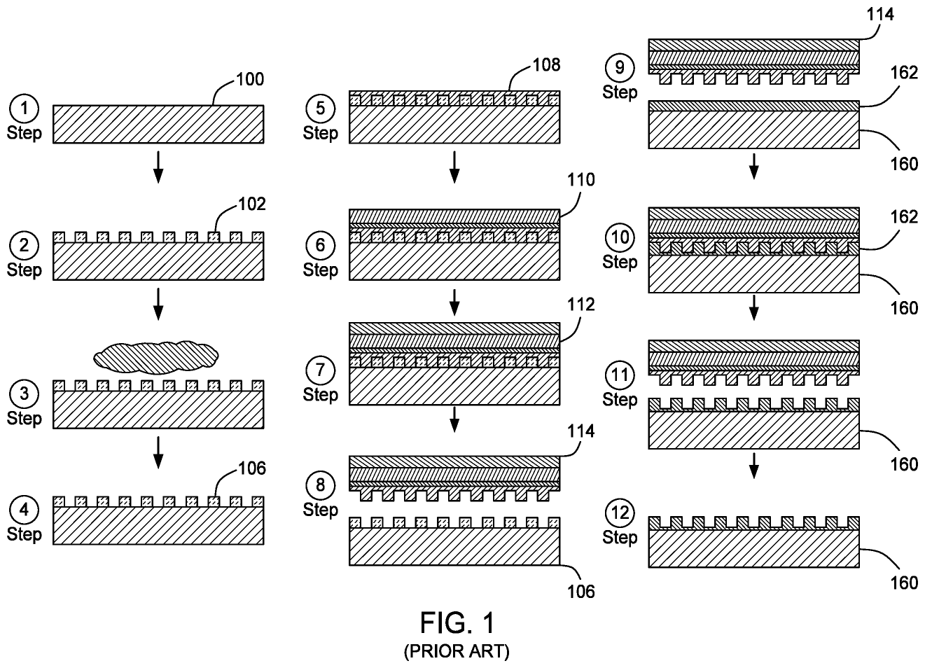

FIG. 1 illustrates a PDMS stamp for imprinting. In this conventional process a PDMS stamp fabrication sequence uses a binary fin grating as an example. In step 1, an imprint master fabrication starts with a host substrate 100 such as a silicon wafer. In step 2, the host substrate 100 is processed with a coating layer 102 and the coating layer is patterned using a photolithography tool. In step 3, the patterned substrate is surface treated with an anti-stick monolayer. In step 4, the patterned substrate master 106 is ready for stamp making. In step 5, a higher modulus PDMS layer 108 is spun onto the patterned master surface and cured. In step 6, a modulus transition layer (or adhesion layer) 110 is applied and then cured. In step 7, a controlled air gap 112 is formed between the top PDMS stack surface and the bottom glass backing. Soft PDMS is introduced to fill the air gap and then thermally cured in place. In step 8, the cured PDMS stamp assembly 114 is carefully released from the master substrate 106. In step 9, the PDMS stamp 114 is positioned over a target imprint substrate 160 coated with imprint resist 162. In step 10, the PDMS stamp is placed in physical contact with the resist 162 and imprint substrate 160. In step 11, after curing (UV or thermal) the sandwiched stack assembly, the PDMS stamp is released and separated from the imprint substrate 160. In step 12, the imprint substrate 160 now has the imprinted pattern on its surface.

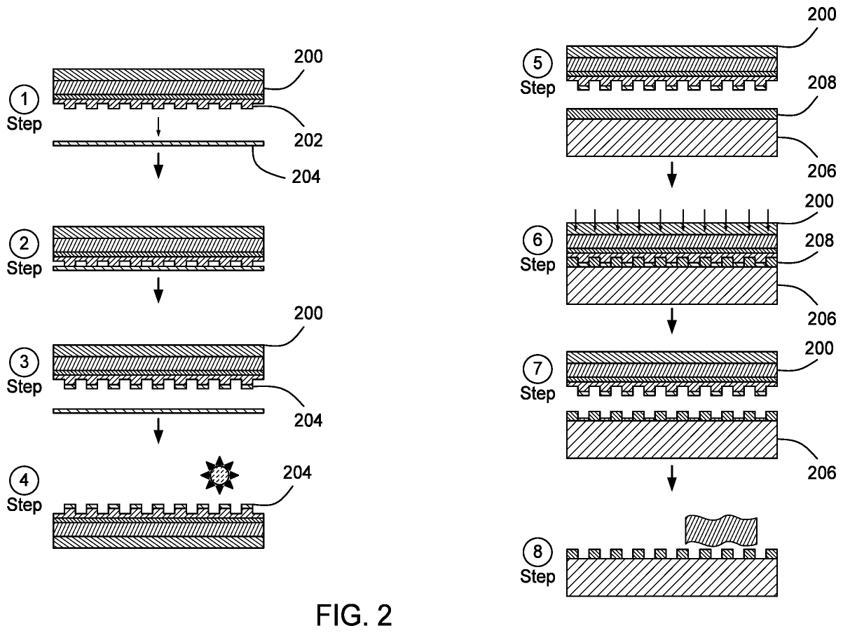

In another non-limiting embodiment of the disclosure, a method is disclosed for a UV blocking layer stamp pickup fabrication method for a PDMS stamp. Referring to FIG. 2, a binary fin grating stamp 200 is provided in step 1. This stamp is then coated, in step 2 on the exterior bottom edges 202 with a UV blocking material 204. Step 3 provides the PDMS stamp 200 with the exterior bottom edges 202 coated with the UV blocking material 204. In step 4, the UV blocking material 204 is then cured in place. In step 5, with the UV blocking material 204 cured in place, the stamp 200 is brought to a target imprint substrate 206 coated with imprint resist 208. In step 6, the PDMS modified stamp 200 is placed in physical contact with the resist 208 and imprint substrate 206. In step 7, after curing with ultra violet radiation, the PDMS stamp 200 is released and separated from the imprint substrate 206. The imprint substrate now has the imprinted pattern on its surface, in step 8. In embodiments, the method may include, as a non-limiting embodiment, developing and removal of a residual layer not exposed to ultraviolet radiation.

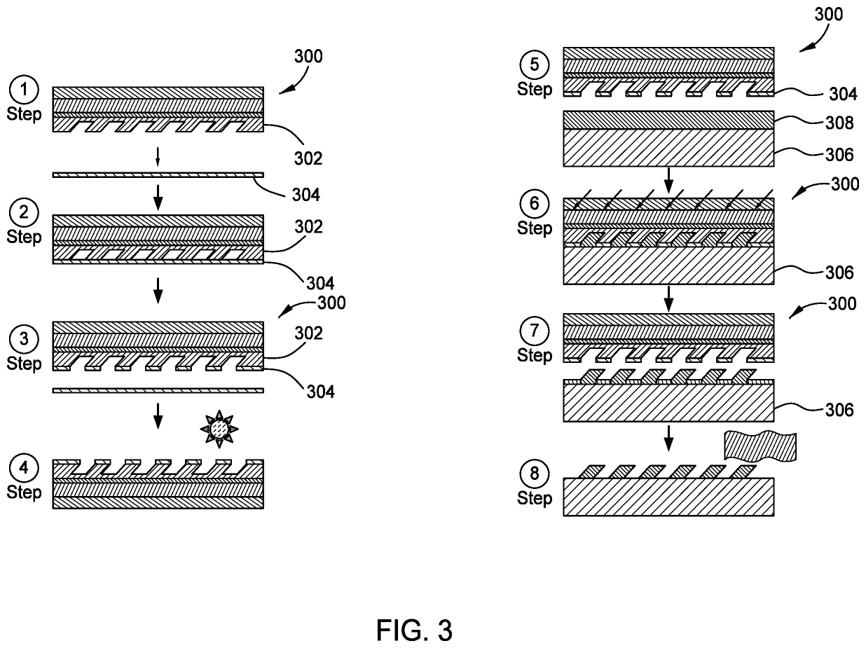

In one non-limiting embodiment of the disclosure, a method is disclosed for a UV blocking layer stamp pickup fabrication method for a PDMS stamp with a slanted fin grating. Referring to FIG. 3, a slanted fin grating stamp 300 is provided in step 1. This stamp is then coated, in step 2 on the exterior bottom edges 302 with a UV blocking material 304. Step 3 provides the PDMS stamp 300 with the exterior bottom edges 302 coated with the UV blocking material 304. In step 4, the UV blocking material 304 is then cured in place. In step 5, with the UV blocking material 304 cured in place, the stamp 300 is brought to a target imprint substrate 306 coated with imprint resist 308. In step 6, the PDMS modified stamp 300 is placed in physical contact with the resist 308 and imprint substrate 306. In step 7, after curing with ultra violet radiation, the sandwiched stack assembly, the PDMS stamp 300 is released and separated from the imprint substrate 306. The imprint substrate now has the imprinted pattern on its surface, in step 8. In embodiments, the method may include, as a non-limiting embodiment, developing and removal of a residual layer not exposed to ultraviolet radiation.

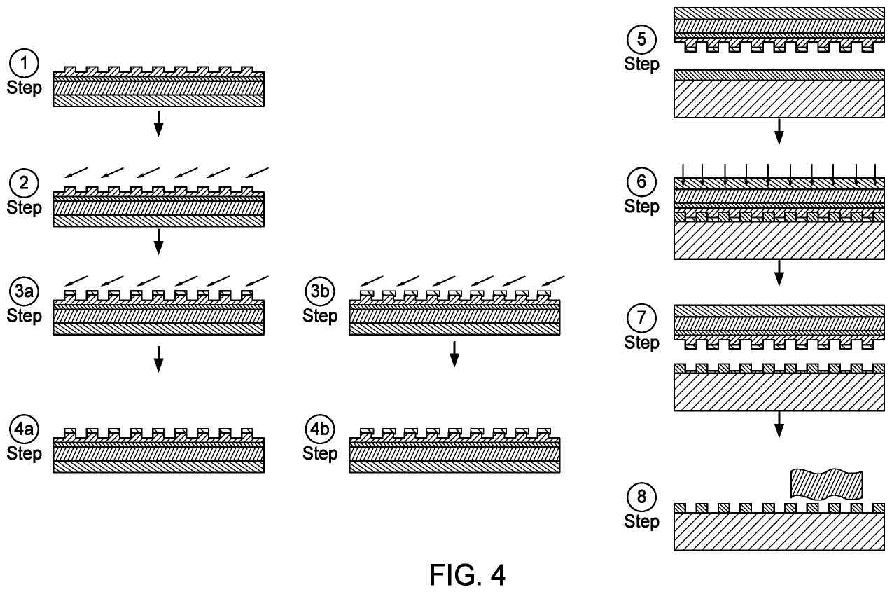

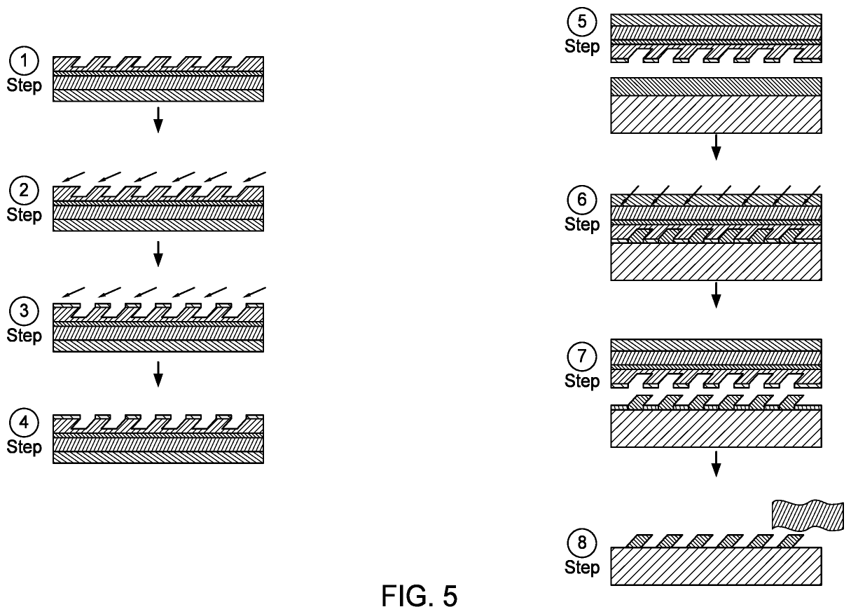

Referring to FIG. 4, another example embodiment of the disclosure is illustrated. In this illustrated embodiment, a binary fin grating stamp forms the UV blocking material at the protruding tips by an angled deposition of the material. In step 1, a binary fin grating stamp is provided. In step 2, an angled deposition occurs. In this step, the materials build on binary fins from the deposition in 3a and 4a where the UV blocking material is deposited on top of the binary fins. At the conclusion of the deposition, the UV blocking material is positioned on the binary fins at illustrated in step 4a or 4b. Alternatively, the materials build on binary fins can take the form as depicted in steps 3b and 4b where the UV blocking material is deposited on top of the binary fins and also slightly on the sidewall facing the deposition source. This is slightly less than ideal but, in embodiments, will work in placement of the UV blocking material. In step 5, the modified PDMS stamp is positioned over a target imprint substrate coated with imprint resist. The PDMS modified stamp is then placed in physical contact with the resist and the imprint substrate. At step 7, after curing in ultraviolet light, the PDMS stamp is released and separated from the imprint substrate. At step 8, the imprint substrate now has the imprinted pattern on its surface. In FIG. 5, steps 1-8, a similar process is disclosed for slanted fin grating arrangements.

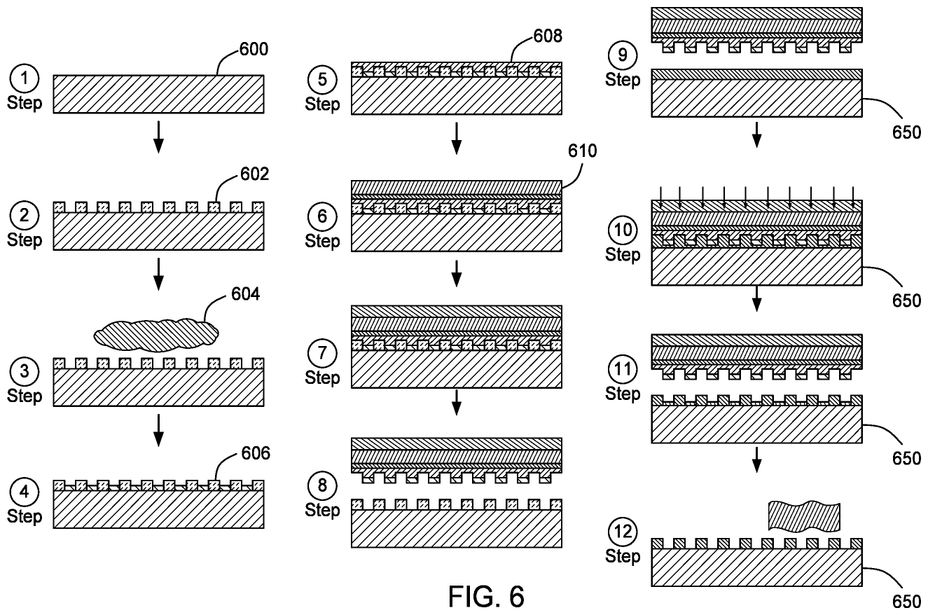

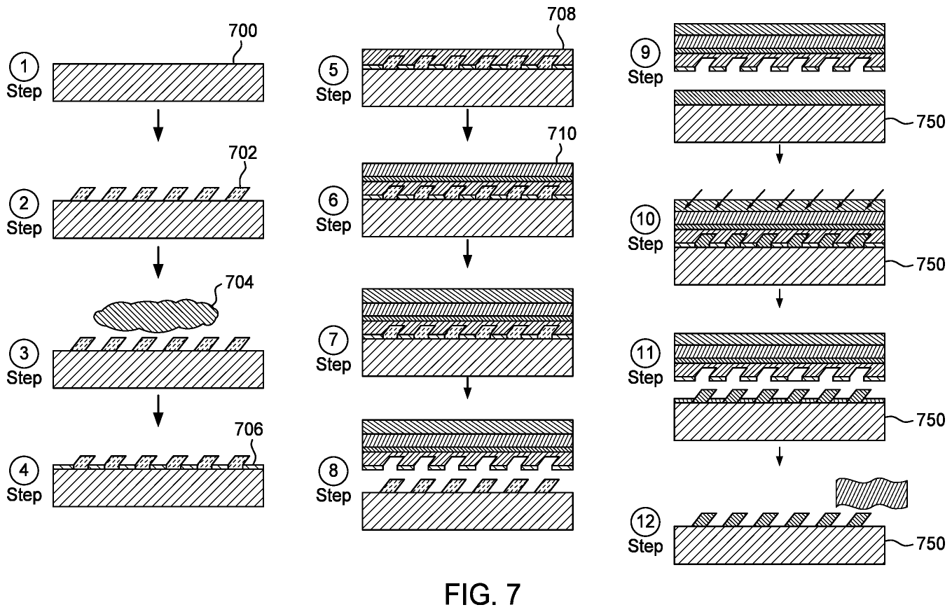

Referring to FIG. 6, an underfill for a binary fin grating master gap is provided, wherein the underfilling is with a UV blocking layer. A similar process for slanted fin gratings in illustrated in FIG. 7. In embodiments, the method may include, as a non-limiting embodiment, developing and removal of a residual layer not exposed to ultraviolet radiation. In step 1, an imprint master fabrication starts with a host substrate such as a silicon wafer 600, 700. In step 2, the host substrate 600, 700 is processed with a coating layer and the coating layer 602, 702 is patterned using a photo lithography tool. In step 3, the patterned substrate is surface treated with an anti-stick monolayer 604, 704. In step 4, the patterned substrate master is now ready for stamp making. The gaps are underfilled with a UV blocking layer 606, 706. In step 5, a higher modulus PDMS layer is spun onto the patterned master surface and cured 608, 708. In step 6, the modulus transition (or adhesion layer 610, 710) is applied and then cured. In step 7, a controlled air gap is formed between the top PDMS stack surface and the bottom backing. The soft PDMS is introduced to fill the air gap and then thermally cured in place. In step 8, the cured PDMS stamp assembly is carefully released from the master substrate 600, 700 taking the ultraviolet blocking layer with it. In step 9, the modified PDMS stamp is positioned over a target imprint substrate 650, 750 coated with imprint resist. In step 10, the PDMS modified stamp is placed in physical contact with the resist and imprint substrate 650, 750. After curing (with ultra violet radiation), the PDMS stamp (step 11) is released and separated from the imprint substrate 650, 750. In step 12, the imprint substrate 650, 750 now has the imprinted pattern on its surface.

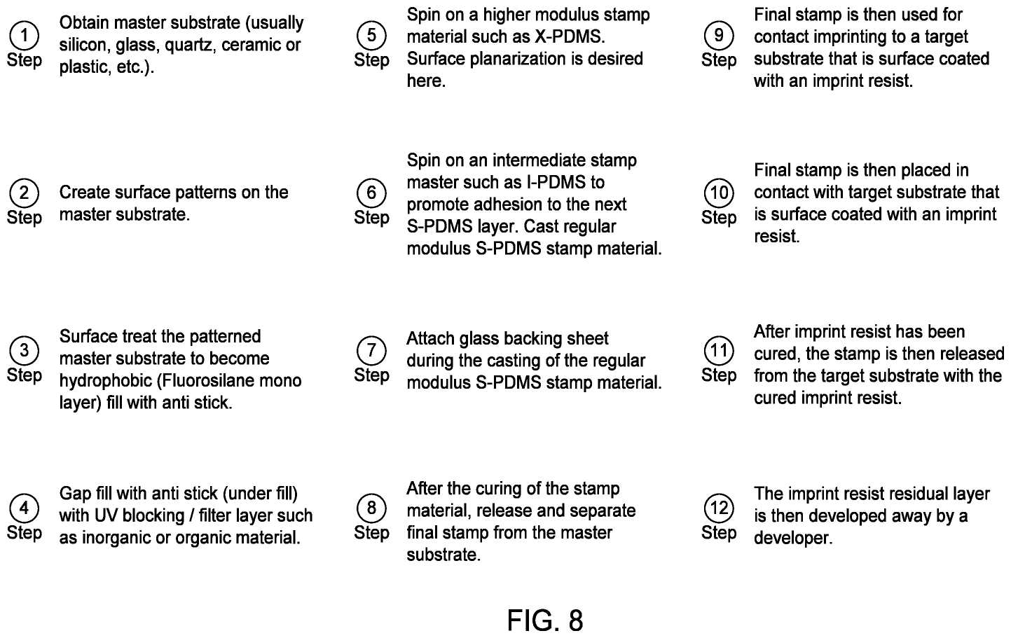

Referring to FIG. 8, another example method for an underfilled UV blocking layer for a PDMS stamp is disclosed. In step 1, a master substrate is obtained. The master substrate may be silicon, glass, quartz, ceramic or plastic. In step 2, surface patterns are created on the master substrate. In step 3, a surface treatment is performed such that the patterned master substrate is hydrophobic. In step 4, gaps are filled (under filled) with a UV blocking/filter layer such as an inorganic or organic material. In step 5, a higher modulus stamp material is spun onto the stamp. Materials such as X-PDMS may be used. Surface planarization may occur in this step. In step 6, an intermediate stamp material may be spun such as I-PDMS to promote adhesion to the next S-PDMS layer. Regular modulus S-PDMS may be also cast in this step. In step 7, a glass backing sheet may be attached during the casting of the regular modulus S-PDMS stamp material. In step 8, after curing of the stamp material, the final stamp may be released and separated from the master substrate. In step 9, the final stamp is then used for contact imprinting to a target substrate that is surface coated with an imprint resist. In step 10, the final stamp is then placed in contact with a target substrate that is surface coated with an imprint resist. In step 11, after the imprint resist has been cured, the stamp is then released from the target substrate with the cured imprint resist. In step 12, the imprint resist residual layer is then developed away by a developer.

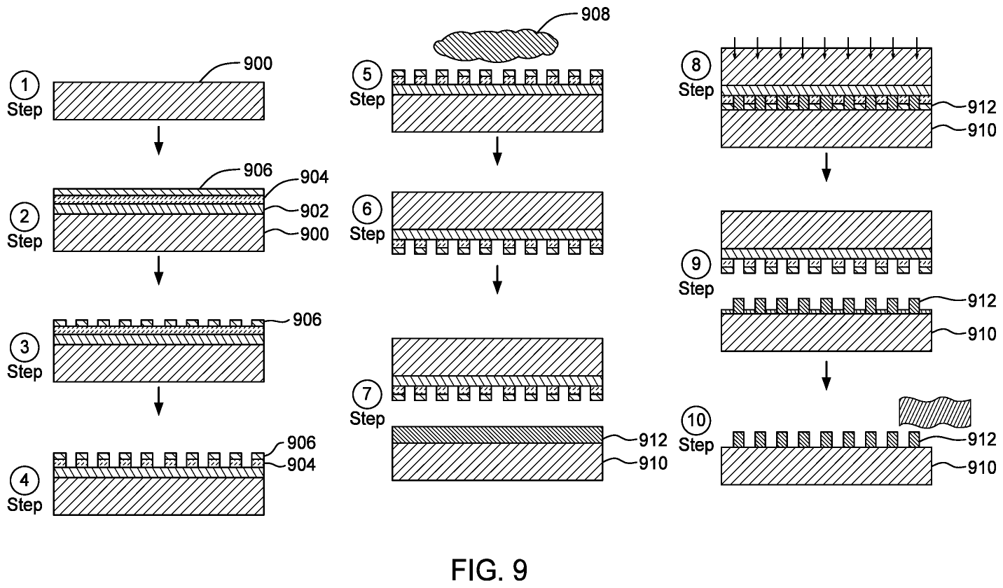

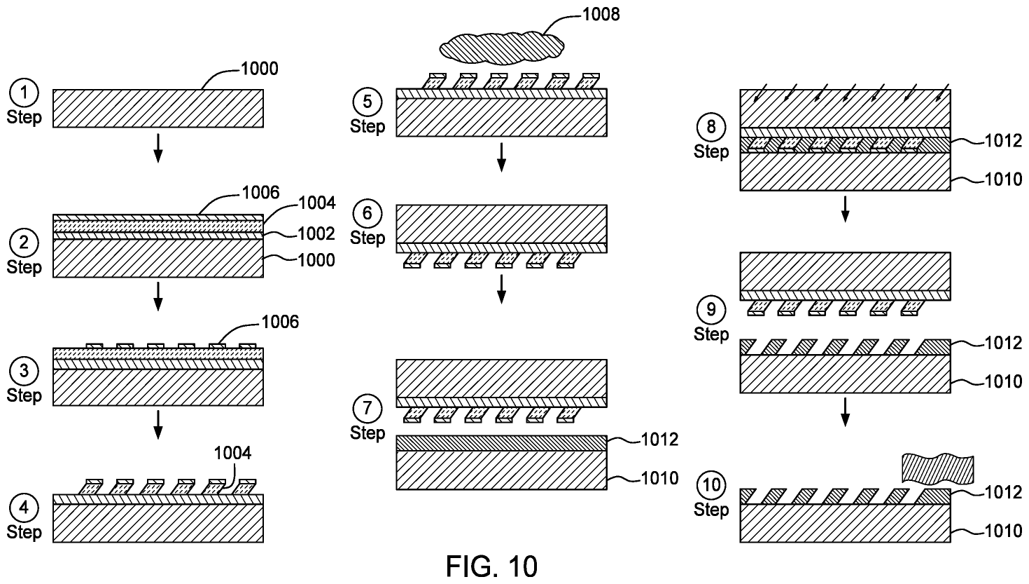

Referring to FIG. 9, as opposed to other methods described, a hard or a flexible stamp substrate is used and correspondingly, a softer or harder target imprint substrate is further provided. In step 1, for example, a hard stamp substrate 900 is used. In step 2, the hard stamp substrate 900 is covered by three layers of material 902, 904, 906. In step 3, portions of the outermost layer 906 are removed providing a surface pattern. In step 4, further material is removed out of the second layer 904. In step 5, the patterned substrate is surface treated with an anti-stick monolayer 908. The entire arrangement may be then inverted in step 6, and used for stamping. In step 7, the stamp is positioned over a target imprint substrate 910 coated with imprint resist 912. In step 8, the stamp is placed in physical contact with the resist 912 and imprint substrate 910. After curing (with ultra violet radiation), the sandwiched stack assembly, the stamp is released (step 9) and separated from the imprint substrate 910. In step 10, the imprint substrate 910 now has the imprinted pattern 912 on its surface and any non-ultraviolet exposed residual layer can be developed away. Additional curing may occur after step 10. A similar process for slanted fin gratings in illustrated in FIG. 10.

Referring to FIG. 10, as opposed to other methods described, a hard or a flexible stamp substrate 1000 is used and correspondingly, a softer or harder target imprint substrate is further provided. In step 1, for example, a hard stamp substrate 1000 is used. In step 2, the hard stamp substrate is covered by three layers of material 1002, 1004, 1006. In step 3, portions of the outermost layer 1006 are removed, providing a surface pattern. In step 4, further material is removed out of the second layer 1004 in a slanted grating pattern. In step 5, the patterned substrate is surface treated with an anti-stick monolayer 1008. The entire arrangement may be then inverted in step 6, and used for stamping. In step 7, the stamp is positioned over a target imprint substrate 1010 coated with imprint resist 1012. In step 8, the stamp is placed in physical contact with the resist 1012 and imprint substrate 1010. After curing (with ultra violet radiation), the stamp is released (step 9) and separated from the imprint substrate. In step 10, the imprint substrate now has the imprinted pattern on its surface. Additional curing may occur after step 10.

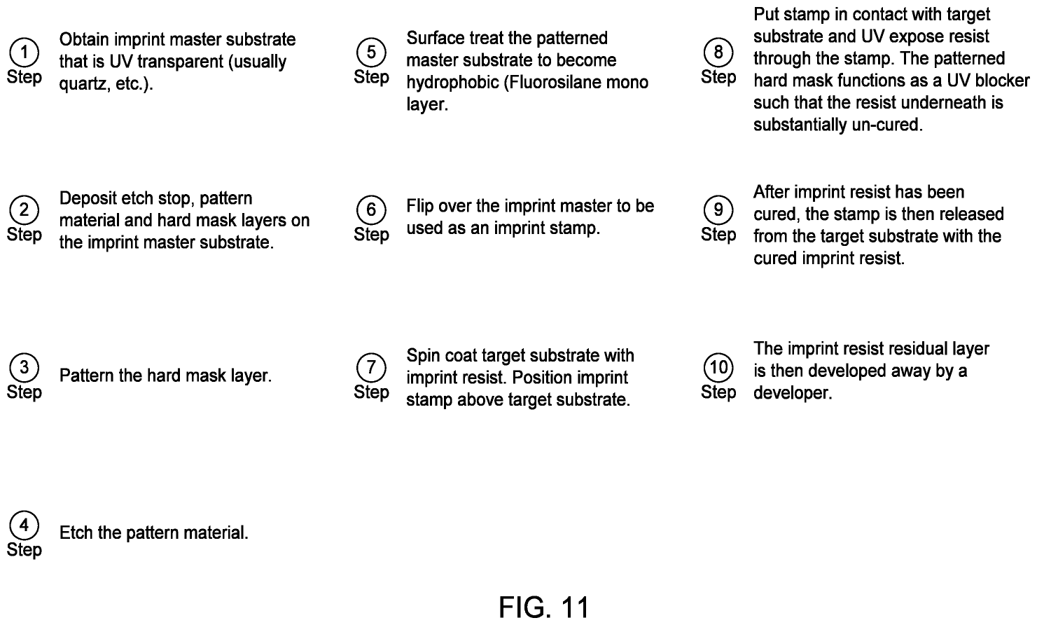

Referring to FIG. 11, a method for making an imprint master with UV blocking patterns is illustrated. In step 1, an imprint master substrate is obtained. The master substrate is transparent to UV. Materials such as quartz may be used. In step 2, etch stop is deposited as well as pattern material and hard mask layers on the imprint master substrate. In step 3, the hard mask is patterned. In step 4, the pattern material is then etched. In step 5, the patterned master substrate is then anti-stick coated to be hydrophobic. The imprint master is then flipped in step 6, to be used as an imprint stamp. In step 7, the spin coat target substrate is spun with imprint resist. The imprint stamp is positioned above a target substrate. In step 8, the stamp is put in contact with a target substrate and UV exposure is provided through the stamp. The patterned hard mask functions as a UV blocker such that the resist underneath is substantially un-cured. In step 9, after imprint resist has been cured, the stamp is then released from the target substrate with the cured imprint resist. In step 10, the imprint resist residual layer is then developed away by a developer.

Other aspects of the disclosure aim to reduce, minimize, or remove imprint residual layer thickness (RLT) for nano imprint lithography that uses radiation curable imprint resists. Imprint mold patterned protruding features that will make close contact with the imprint substrates are made to be radiation blocking such that the radiation coming from behind the mold will not cure the imprint resist under these protruding features. These protruding features are where the field residual layer normally resides. After the release of the imprint mold, these uncured imprint resist are removed by dissolving or etching these material (using liquid or gas techniques). Further removal of RLT residuals can be achieved by a descum method.

The radiation blocking layers at the imprint mold patterned protruding features can be fabricated by various means. For some imprint transfer operations that require high pattern fidelity, the imprint molds are usually fabricated with hard, rigid stamp material that are light radiation transparent like quartz or glass. Other mold stamp materials can be soft PDMS or a hybrid stamp material system that utilize multiple stamp layers. Radiation blocking layer can be fabricated out of a metal or metal oxide layer to a thickness to block or filter the radiation. A typical metal will be chrome or TiN which are typically used as a hard etch mask. Another method of creating such a radiation blocking layer may be through direct surface contact such that the mold surface is altered by material adhesion or material alteration.

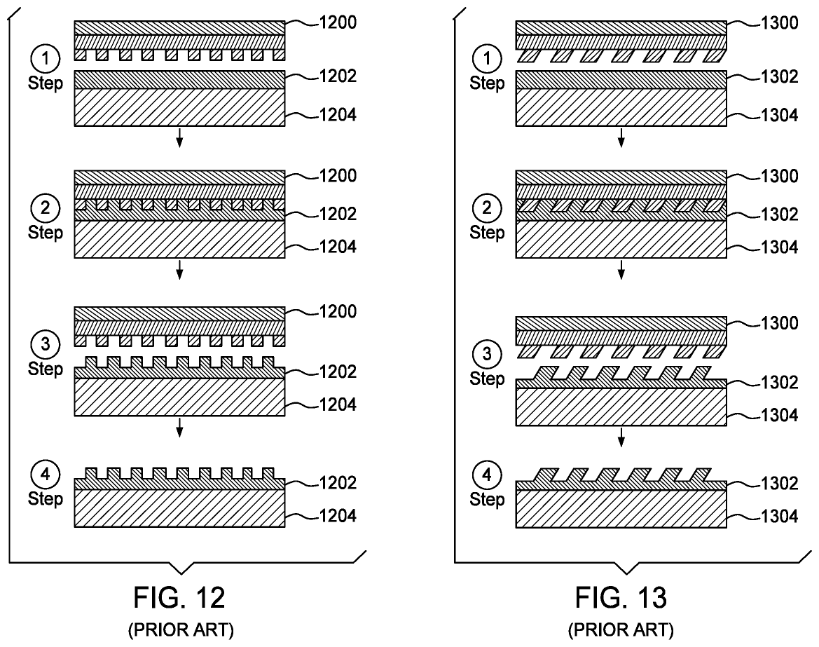

Referring to FIG. 12, a prior art method for imprinting a substrate is illustrated. In step 1, a stamp 1200 is positioned over a target substrate 1204 that is covered with imprint resist 1202. In step 2, contact is established between the stamp 1200 and the target substrate 1204 covered with imprint resist 1202. In step 3 the stamp 1200 and the target resist 1202 are released. In step 4, the result is an imprint in the resist layer 1202 placed upon the substrate 1204. In a likewise method, referring to FIG. 13, a prior art method for imprinting a substrate 1304 is illustrated. In this method, a slanted fin grating is provided. In step 1, a stamp 1300 is positioned over a target substrate 1304 that is covered with imprint resist 1302. In step 2, contact is established between the stamp 1300 and the target substrate 1304 covered with imprint resist 1302. In step 3, the stamp 1300 and the target resist 1302 are released. In step 4, the result is an imprint in the resist layer 1302 placed upon the substrate 1304.

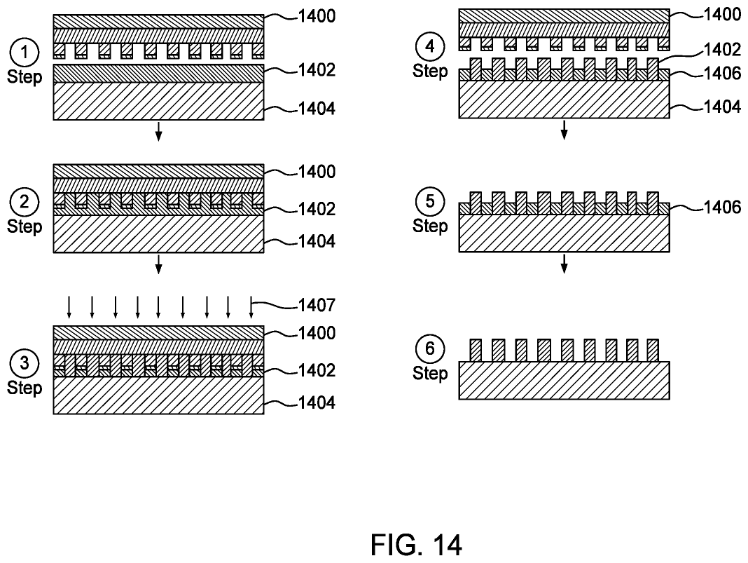

Referring to FIG. 14, a method for nano-imprint of a substrate is illustrated, in accordance with another example embodiment of the disclosure. The method presented is substantially different than the methods presented in FIGS. 12 and 13 in that nano-particle resist is used. The use of nano-particle resist, previously not known, allows for much smoother and accurate results. In step 1, a stamp 1400 is placed over a substrate 1404 covered with a layer of nano-particle resist 1402. In step 2, contact is established between the substrate 1404 covered with the layer of resist 1402 and the stamp 1400. In step 3, radiation 1407 is imparted into the stamp and the substrate covered with the layer of resist. The radiation penetrates the stamp 1400 as the stamp 1400 is made of material that is transparent to the radiation. Pressure may also be exerted during this step. A curing of the resist occurs while the stamp 1400 and substrate 1404 covered with the layer of resist 1402 are connected and exposed to radiation. In step 4, the stamp 1400 is withdrawn from the substrate 1404 leaving an imprint in the resist 1402 and a layer of residual resist 1406 as illustrated in step 5. In step 6, the residual resist 1406 may then be removed to leave a full depth replica of the stamp 1400.

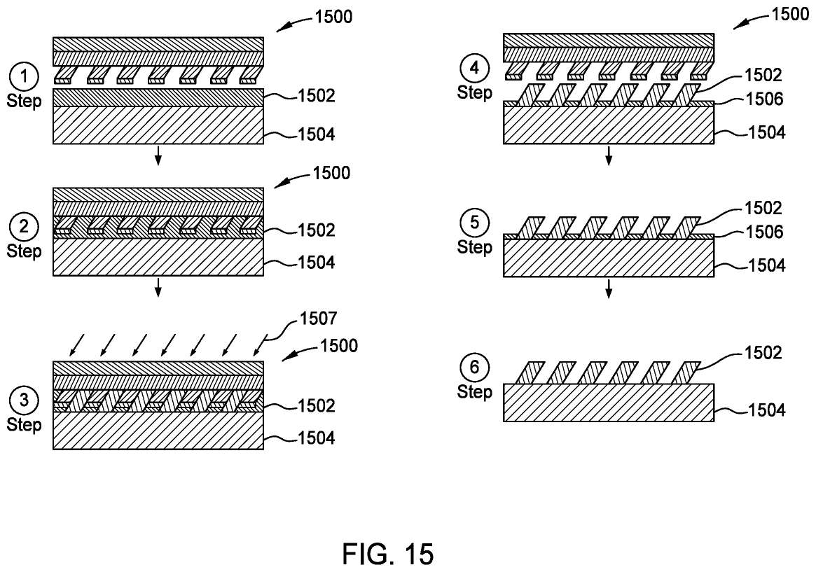

Referring to FIG. 15, a method for nano-imprint of a substrate with slanted fin grating is illustrated, in accordance with another example embodiment of the disclosure. In step 1, a stamp 1500 is placed over a substrate 1504 covered with a layer of nano-particle resist 1502. In step 2, contact is established between the substrate 1504 covered with the layer of resist 1502 and the stamp 1500. In step 3, radiation 1507 is imparted into the stamp 1500 and the substrate 1504 covered with the layer of resist 1502. The radiation penetrates the stamp 1500 as the stamp 1500 is made of material that is transparent to the radiation. A curing occurs while the stamp 1500 and substrate 1504 are connected and exposed to radiation. In step 4, the stamp 1500 is withdrawn from the substrate 1504 leaving an imprint in the resist 1502 and a layer of residual resist 1506. The residual resist 1506 may then be removed to leave a full depth replica of the stamp 1500.

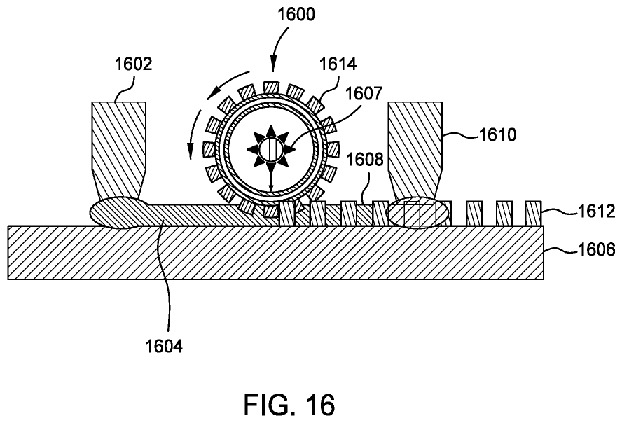

Referring to FIG. 16, a method for producing an imprint on a substrate is illustrated using roll-to-roll imprinting technology. A substrate 1606 is provided that a user desires to place an imprint upon. The substrate 1606 may be stationary or on a moving apparatus, such as a conveyor. A layer of resist 1604 is placed upon the substrate 1606 through a port 1602. The amount of resist (thickness) 1604 may be controlled to minimize the amount of resist used and to ensure that minimal excess must be removed. In a moving substrate, the viscosity of the resist, the angle of contact between the port 1602, the temperature, the pressure and the motion of the substrate 1606 may be controlled to provide an optimal thickness of resist 1604. The layer of resist 1604 is then contacted by protrusions 1614 on a roll assembly 1600. The roll assembly 1600 is arranged to move at the desired speed in conjunction with the substrate 1606 such that the protrusions 1614 contact the layer of resist 1604. Radiation 1607 may be imparted into the layer of resist as the substrate moves underneath the roll assembly 1600. The radiation may be ultra violet radiation, heat or a combination of both as non-limiting embodiments. At point 1608, the protrusions are imprinted within the layer of resist 1604 and an amount of excess resist is present between the protrusions 1608. At 1610, an arrangement is provided such that excess resist is removed from the protrusions to result in a final layer 1612 of protrusions upon the substrate 1606. As illustrated, nano-particle resist may be used for the steps provided in FIG. 16.

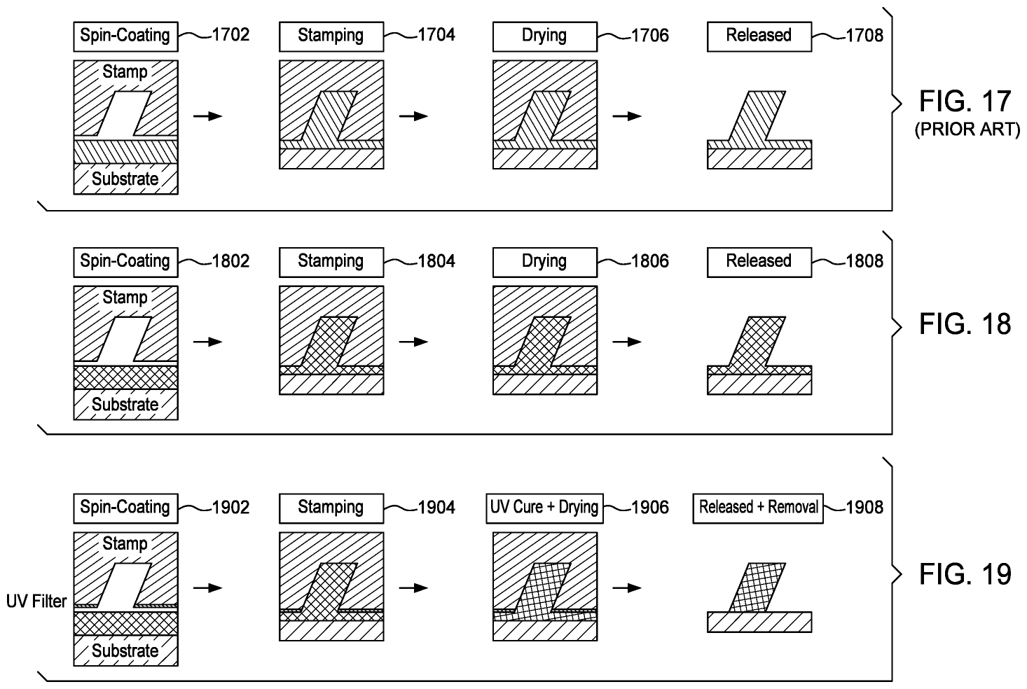

Referring to FIG. 17, a prior art method for providing an imprint upon a substrate is illustrated. In 1702, a substrate is provided underneath a stamp. Spin coating is then performed such that resist fills a void between the stamp and the substrate. In 1704, an illustration of the filled void is provided. A drying process 1706 is provided such that the filled void may be cured. After release, in 1708, a final product is illustrated. Potential drawbacks include rough side walls due to particle distribution and non-uniformity. The size of the particles in this method are between 10 and 1000 nm, substantially different than nanoparticle resist.

Referring to FIG. 18, a method for using nano-particles, such as titanium dioxide is presented. Such nano-particles may range from 2 to 50 nanometers in diameter with an inorganic core and organic/inorganic ligand exterior. In 1802, a stamp is placed over a substrate, with a void between the substrate and the stamp. Spin coating is then performed, wherein resist material fills the void, as illustrated in 1804 with the process of stamping. In 1806, drying occurs such that the resist materials within the void (the nano-particle resist) dries. After release, the void is filled as illustrated in 1808. Several advantages to this method exist, including lower sidewall roughness, thinner residual nanoparticles at the bottom of the mask (void) and a uniform placement of nanoparticles.

Referring to FIG. 19, a method for nano-particle resist usage for making a protrusion feature through UV curing and drying is illustrated. In 1902, a stamp is placed over a substrate and spin-coating is performed. The nano-particles used may be, for example, titanium dioxide, that are <50 nano-meters in size. In 1904, a stamping occurs and the void is filled with resist. In 1906, a UV curing and drying takes place for the layer of resist upon the substrate. After release an accurate replica of the protrusion is produced in the resist after developing out the residual thickness layer (RTL) as depicted in 1908. Such methods provide for low sidewall roughness, no residual nano-particles at the bottom of the fin structure.

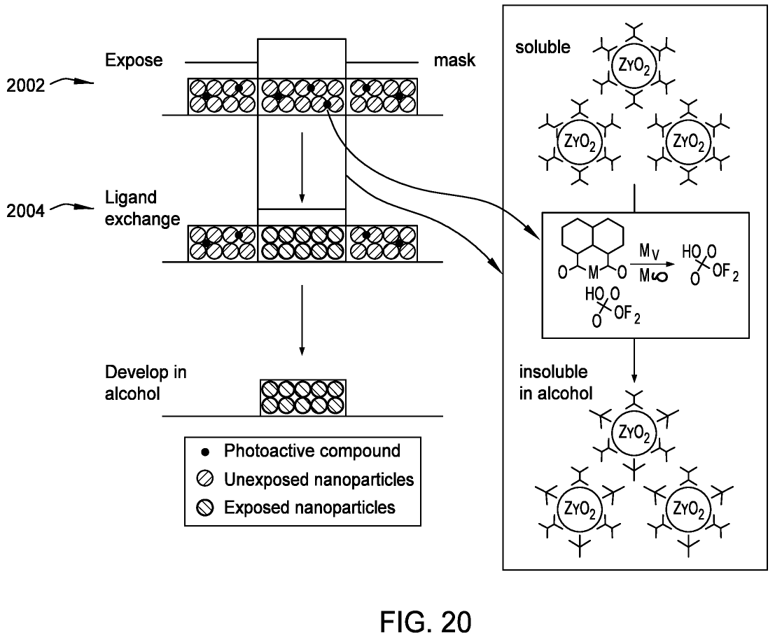

Referring to FIG. 20, a process flow is illustrated wherein the resist is solidified upon radiation exposure. Development may occur with alcohol. In 2002, photoactive compounds are placed in close conjunction with unexposed nanoparticles. In 2004, a ligand exchange occurs wherein some particles are soluble in alcohol and some particles are insoluble in alcohol. After ligand exchange in 2004, development in alcohol occurs, resulting in an arrangement of resist in a required arrangement.

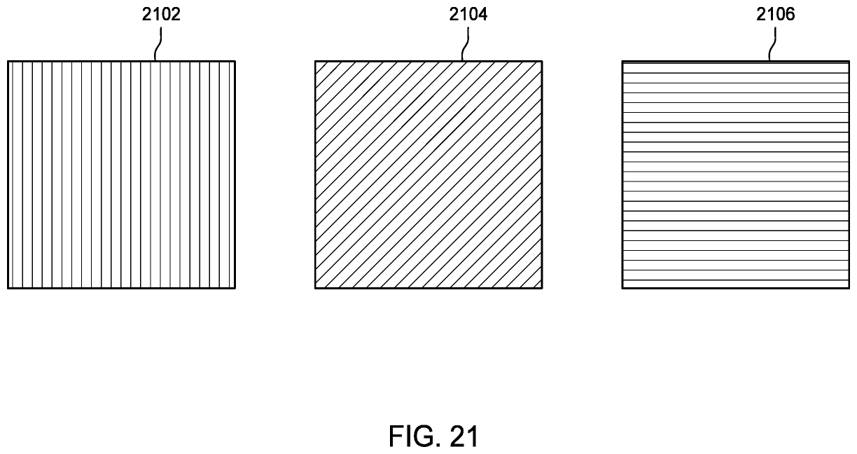

Referring to FIG. 21, an example imprint of resist according to an example method is illustrated. In 2102 a 4 inch silicon wafer is provided, being processed UV belt furnace conveyor belt speed of 13 feet per minute rate is illustrated. Imprint resist of titanium dioxide-Al+H2O2 is used. The results in 2102, 2104 and 2106 show good imprinting during the process of imprinting and drying and curing.

In embodiments, aspects of the disclosure may be used in conjunction with wire grid polarizers. Conventional wire grid polarizers are typically lithographically patterned and etched with features of line widths below 500 nm. Patterning is usually done with high end lithographic aligners or are nano imprinted. Aspects of the disclosure herein, however, propose use of a residual layer free layer. The leave on resist material may function as a wire grid polarizer. This layer that is left may be formulated using a nano particle based dispersion or liquid based precursor, as necessary.

In one non-limiting embodiment, a method of producing a copy of a stamp for generating electrical/optical components is disclosed, comprising: providing the stamp; coating a bottom surface of the stamp with a ultra violet blocking material; curing the ultra violet blocking material on the bottom surface; contacting the stamp to a target substrate covered with a layer of imprint resist; curing the imprint resist with ultraviolet blocking material during the contacting of the stamp to the target substrate; and releasing the stamp from the target substrate with the cured layer of imprint resist.

In another non-limiting embodiment, the stamp may have a dual fin configuration. In another non-limiting embodiment, the stamp may have a slanted fin configuration. In another non-limiting embodiment, the curing of the ultra violet blocking material on the bottom surface is through heat input. In another non-limiting embodiment, the curing of the ultra violet blocking material on the bottom surface is through added pressure.

In another non-limiting embodiment, a method for producing a stamp is disclosed, comprising: providing a host substrate, coating the host substrate with coating layer, processing the host substrate with the coating layer with a photolithography tool to produce a surface to be replicated, treating the surface to be replicated with an anti-stick material, filling gaps of the stamp with a ultra violet blocking layer, curing the ultra violet blocking layer, placing a layer of material on to the surface to be replicated with the ultra violet blocking layer, placing an adhesion layer to the layer of material on the surface to be replicated to produce an arrangement, producing a controlled air gap between the arrangement and a backing, filling the controlled air gap with polydimethylsiloxane, curing the gap filled with the polydimethylsiloxane, separating the arrangement with the backing at the anti-stick material, producing a top stamp portion, placing the top stamp portion over a target imprint substrate with a layer of resist, contacting the top stamp portion to the target imprint substrate with the layer of resist, curing the layer of resist on the target imprint substrate, and removing the top stamp portion from the target imprint substrate with the layer of resist.

In another non-limiting embodiment, the method may be accomplished wherein the placing the material on to the surface is through a process of spin coating. In another non-limiting embodiment, the method may be accomplished wherein the anti-stick material is a monolayer material.

In another non-limiting embodiment, a method of making an electrical/optical component is disclosed comprising: placing a stamp containing a surface for replicating the electrical/optical component over a substrate covered with a layer of resist, stamp having a surface coating of ultra violet blocking material, establishing contact between the substrate covered with the layer of nanoparticle resist and the stamp, imparting radiation to the substrate covered with the layer of nano-particle resist and the stamp, solidifying at least a portion of the nano-particle resist with the radiation not protected by the ultra violet blocking material, separating the nano-particle resist covered substrate from the stamp; and removing sections of residual resist from the stamp.

In another non-limiting embodiment, the method may be accomplished wherein the electrical/optical component is a binary fin grating. In another non-limiting embodiment, the method may be accomplished wherein the electrical/optical component is a slant fin grating. In another non-limiting embodiment, the method may be accomplished, wherein the nano-particle resist is made of materials that are under 50 mm in diameter. In another non-limiting embodiment, the method may be accomplished, wherein the nano-particle resist is made at least partially from titanium dioxide. In another non-limiting embodiment, the method may be accomplished wherein the nano-particle resist is made of at least an inorganic metal oxide core. In another non-limiting embodiment, the method may be accomplished wherein the nano-particle resist further comprises an organic/inorganic ligand shell over the inorganic metal oxide core. In another non-limiting embodiment, the method may further comprise developing a remainder of the surface coating with the ultra violet blocking material and a developer. In another non-limiting embodiment, the method may be performed wherein the developing may occur through contact with alcohol. In another non-limiting embodiment, the method may be accomplished wherein the ultra violet blocking material is configured to block at least one of solvents and materials from an imprint resist.

While embodiments have been described herein, those skilled in the art, having benefit of this disclosure will appreciate that other embodiments are envisioned that do not depart from the inventive scope of the present application. Accordingly, the scope of the present claims or any subsequent related claims shall not be unduly limited by the description of the embodiments described herein.

What is claimed is:

1. A method, comprising:
disposing an etch stop layer over a stamp substrate, a pattern material over the etch stop layer, and an ultraviolet (UV) blocking hard mask over the pattern material;
patterning the UV blocking hard mask to expose a surface pattern in the pattern material;
etching the surface pattern in the pattern material to form a stamp having stamp structures;
imprinting an imprint resist disposed on a target substrate with the stamp, the imprint resist having device portions defined by adjacent stamp structures and residual portions disposed under the UV blocking hard mask;
exposing the stamp and the imprint resist to UV exposure, the UV blocking hard mask protecting the residual portions of the imprint resist from the UV exposure such that the device portions are cured and the residual portions are uncured; and
removing the stamp and developing the imprint resist to remove the residual portions that are uncured from the target substrate.

2. The method of claim 1, further comprising:
treating the stamp with an anti-stick material such that the stamp is hydrophobic.

3. The method of claim 2, wherein the anti-stick material is a fluorosilane monolayer material.

4. The method of claim 1, wherein the removing the residual portions from the target substrate further includes etching or descumming the residual portions.

5. The method of claim 1, wherein the stamp substrate is transpatent to the UV exposure.

6. The method of claim 1, wherein the stamp substrate is a quartz material. A method, comprising:
disposing an etch stop layer over a stamp substrate, a pattern material over the etch stop layer, and an ultraviolet (UV) blocking hard mask over the pattern material;
patterning the UV blocking hard mask to expose a surface pattern in the pattern material;
etching the surface pattern in the pattern material to form a stamp having slanted stamp structures;
imprinting an imprint resist disposed on a target substrate with the stamp, the imprint resist having device portions defined by adjacent slanted stamp structures and residual portions disposed under the UV blocking hard mask;
exposing the stamp and the imprint resist to UV exposure, the UV blocking hard mask protecting the residual portions of the imprint resist from the UV exposure such that the device portions are cured and the residual portions are uncured; and
removing the stamp and developing the imprint resist to remove the residual portions that are uncured from the target substrate.

8. The method of claim 7, further comprising:
treating the stamp with an anti-stick material such that the stamp is hydrophobic.

9. The method of claim 8, wherein the anti-stick material is a fluorosilane monolayer material.

10. The method of claim 7, wherein the removing the residual portions from the target substrate further includes etching or descumming the residual portions.

11. The method of claim 7, wherein the stamp substrate is transpatent to the UV exposure.

12. The method of claim 7, wherein the stamp substrate is a quartz material.

13. A method, comprising:
disposing an etch stop layer over a stamp substrate, a pattern material over the etch stop layer, and an ultraviolet (UV) blocking hard mask over the pattern material;
patterning the UV blocking hard mask to expose a surface pattern in the pattern material;
etching the surface pattern in the pattern material to form a stamp;
placing the stamp containing a surface for replicating an electrical/optical component over a substrate covered with a layer of nano-particle resist;
establishing contact between the substrate covered with the layer of nano-particle resist and the stamp;
imparting radiation to the substrate covered with the layer of nano-particle resist and the stamp;
solidifying at least a portion of the nano-particle resist with the radiation not protected by the UV blocking hard mask;
separating the nano-particle resist covered substrate from the stamp; and
removing sections of residual resist from the stamp.

14. The method according to claim 13, wherein the electrical/optical component is a binary fin grating.

15. The method according to claim 13, wherein the electrical/optical component is a slant fin grating.

16. The method according to claim 13, wherein the nano-particle resist is made of materials that are under 50 mm in diameter.

17. The method according to claim 13, wherein the nano-particle resist is made at least partially from titanium dioxide.

18. The method according to claim 13, wherein the nano-particle resist is made of at least an inorganic metal oxide core.

19. The method according to claim 18, wherein the nano-particle resist further comprises:
an organic ligand shell over the inorganic metal oxide core.

20. The method according to claim 11, wherein the UV blocking hard mask is configured to block at least one of solvents and materials released from the nano-particle.
